(19) United States
(12) Patent Application Publication
(10) Pub. No.: US 2003/0035452 A1
(43) Pub. Date: Feb. 20, 2003

(54) Surface emitting semiconductor laser device

(76) Inventor: Natsumi Ueda, Tokyo (JP)

Correspondence Address: KNOBBE MARTENS OLSON & BEAR LLP, 2040 MAIN STREET, FOURTEENTH FLOOR, IRVINE, CA, 92614, US

(21) Appl. No.: 10/212,202

(22) Filed: Aug. 2, 2002

(30) Foreign Application Priority Data
Aug. 3, 2001 (JP) 2001-236207
Mar. 22, 2002 (JP) 2002-80989

(51) Int. Cl. H01S 5/00; H01S 3/08

(52) U.S. Cl. 372/45; 372/46; 372/96

(57) ABSTRACT

A surface emitting semiconductor laser device has a pair of DBRs having opposite conductivity types, a pair of cladding layers having opposite conductivity types, an undoped active layer and a current confinement layer. The boundary between the p-type region and the n-type region of the laser device resides within the active layer, thereby reducing the operating voltage of the laser device.

### BACKGROUND OF THE INVENTION

1. Field of the Invention

The present invention relates to a surface emitting semiconductor laser device and, more particularly, to a current-confinement surface emitting semiconductor laser device, which operates at a lower threshold current and a lower operating voltage.

2. Description of the Related Art

The surface emitting semiconductor laser device, which emits laser light in a direction perpendicular to the substrate surface, has recently received large attention in the data communication field. One of the reasons for the large attention is that unlike the conventional Fabry-Perot resonator semiconductor laser device, a plurality of surface emitting semiconductor laser devices can be arranged in a two-dimensional array on a single substrate.

The surface emitting semiconductor laser device has a pair of semiconductor multilayer reflectors each acting as a DBR and including a plurality of AlGaAs/GaAs layer pairs. The pair of DBRs are different in the conductivity type from each other and are formed to overlie a semiconductor substrate, such as GaAs or InP substrate. The surface emitting semiconductor laser device has an active layer or QW active layer structure sandwiched between the pair of DBRs for laser emission.

In particular, the GaAs-based surface emitting semiconductor laser device can be formed on a GaAs substrate, and have the pair of DBRs including AlGaAs-based layers, which have an excellent thermal conductivity and a high reflectivity. Thus, the GaAs-based surface emitting semiconductor laser device is expected as a light source for use in a 0.8 μm to 1.0 μm band.

The GaAs-based surface emitting semiconductor laser device has a laser emission region sandwiched between DBRs each including semiconductor multilayer films, which are doped with p-type and n-type impurities, respectively. The laser emission region includes, for example, an undoped lower AlGaAs cladding layer having an aluminum (Al) ratio of 0.3, an undoped GaAs/AlGaAs multiple quantum well structure having an Al ratio of 0.2, and an undoped upper AlGaAs cladding layer having an Al ratio of 0.3.

Typically, there are two types of the current confinement structure available for increasing the current injection efficiency and lowering the threshold current of the surface emitting semiconductor laser device: a current confinement structure having an ion-implanted p-n junction and a current confinement structure having a selectively oxide layer, the latter being referred as an oxidized current confinement structure hereinafter. The oxidized current confinement structure is such that an AlAs layer is selectively oxidized by a selective oxidation technique to have a central non-oxidized area and a peripheral Al-oxidized area.

The oxidized current confinement structure has an excellent current confinement function and can be achieved by using a relatively simple thermal process. Thus, it is widely employed in the surface emitting semiconductor laser device.

Now, the configuration of a conventional GaAs-based surface emitting semiconductor laser device will be described. FIG. 1 is a schematic sectional view illustrating the conventional GaAs-based surface emitting semiconductor laser device.

The conventional GaAs-based surface emitting semiconductor laser device 10 has a layer structure formed on an n-type GaAs (n-GaAs) substrate 12. The layer structure includes an n-type lower DBR 14 including 35 n-Al_{0.2}Ga_{0 8}As/n-Al_{0 9}Ga_{0.1}As layer pairs, each layer of the lower DBR 14 having a thickness of λ/4 n (where λ is the lasing wavelength of the laser device and “n” is the refractive index of the each layer). The layer structure also includes an undoped Al_{0 3}Ga_{0.7}As lower cladding layer 16, a quantum well (QW) active layer structure 18, and an undoped Al_{0.3}Ga_{0 7}As upper cladding layer 20, a p-type upper DBR 22 including 20 pairs of p-Al_{0.2}Ga_{0.8}As/p-Al_{0 9}Ga_{0 1}As layer pairs, each layer of the upper DBR 22 having a thickness of λ/4 n (where λ is the lasing wavelength of the laser device and “n” is the refractive index of the each layer), and a p-GaAs cap layer 24 having a thickness of 10 nm.

One of the layers of the p-type upper DBR 22 closest to the active layer structure 18 is replaced by an AlAs layer 26 instead of the p-Al_{0.9}Ga_{0.1}As layer. The AlAs layer 26 includes a central non-oxidized area 26A which functions as a current injection area, and a peripheral Al-oxidized area 26B which functions as a current confinement area.

The QW active layer structure 18 has a GaAs/Al_{0 2}Ga_{0 8}As multiple quantum well (MQW) structure, which include three GaAs QW layers each having a thickness of 7 nm and associated Al_{0 2}Ga_{0 8}As barrier layers.

In fabrication of the surface emitting semiconductor laser device of FIG. 1, an annular groove 28 having a width of 20 μm is formed by photolithographic and etching technique in the layer structure so that the upper DBR 22, the upper cladding layer 20, the active layer structure 18, and the AlAs layer 26 are configured to have a circular mesa post structure, the mesa post structure having a diameter of 45 μm at the central portion of the layer structure as viewed in the axial direction thereof.

The Al content of the AlAs layer 26 in the mesa post structure is selectively oxidized from the periphery of the mesa post so as to form the annular Al-oxidized area 26B and left the current injection area 26A as a non-oxidized area having a diameter of 20 μm.

A SiNx film 32 is deposited as a protective film on the entire surface of the layer structure including the side-walls of the groove 28 except for the central area of the top of the mesa post. An annular electrode in contact with the p-GaAs cap layer 24 is provided on the top of the mesa post as a p-side electrode 34. In addition, a Ti/Pt/Au pad 36 is formed as an electrode lead in contact with the p-side electrode 34.

The rear side of the n-GaAs substrate 12 is polished to adjust the thickness of the n-GaAs substrate 12 at 100 μm, for example, and thereafter an n-side electrode 38 is formed on the rear side of the n-GaAs substrate 12.

It is desired that the surface emitting semiconductor laser device have a lower power dissipation in order to expand its use in the optical communication field. To reduce the power dissipation, it is generally effective to reduce the threshold current and the operating voltage of the laser device.

In order to reduce the operating voltage, reduction of the electrical resistance across the layer structure of the compound semiconductor layers, and (2) reduction of the contact resistance between each of the electrodes and an adjacent compound semiconductor layer may be employed.

For example, a modulated doping technique may be available to reduce the resistance of the DBRs, whereas optimization of the alloying process between an electrode metal and a semiconductor layer may be available to reduce the contact resistance between the electrode and the semiconductor layer.

However, in the oxidized current confinement structure, the small laser emission area due to the small current injection area 26A of the current confinement structure is likely to increase the operating voltage of the laser device because of suppression of the higher-order lateral modes. Furthermore, since the degree of the refractive index distribution in the direction perpendicular to the laser emission is stronger in the oxidized current confinement structure compared to that in the p-n junction type current confinement structure, the oxidized current confinement structure is likely to cause the surface emitting laser device to lase in higher-order modes. For this reason, it is desired that the oxidized current confinement structure have a further smaller current injection area.

Accordingly, even if the conventional GaAs-based surface emitting semiconductor laser device having the oxidized current confinement structure employs the above techniques of (1) and (2) to reduce the electric resistance, it is practically difficult to lower the operating voltage down to 2 volts or lower. Thus, it is difficult to obtain a GaAs-based surface emitting semiconductor laser device, which has the oxidized current confinement structure and yet has a satisfactory lower operating voltage.

In the foregoing, description has been given with respect to the GaAs-based surface emitting semiconductor laser device as an example. However, the above problems are not limited to the GaAs-based laser device, and similar problems are involved in GaInNAs-based or InP-based surface emitting semiconductor laser devices.

### SUMMARY OF THE INVENTION

It is therefore an object of the present invention to provide an oxidized surface emitting semiconductor laser device which operates at a lower threshold current and a lower operating voltage.

The present invention provides an oxidized surface emitting semiconductor laser device that emits laser light in a direction perpendicular to the substrate surface. The oxidized surface emitting semiconductor laser device includes a pair of semiconductor multilayer reflectors, doped with p-type and n-type impurities to have opposite conductivity types, formed overlying a semiconductor substrate, and a laser emission area disposed between the pair of the semiconductor multilayer reflectors, the laser emission area including a pair of cladding layers and an active layer structure sandwiched between the cladding layers.

The oxidized surface emitting semiconductor laser device has a feature that each of the pair of cladding layers is doped with a dopant having a conductivity type same as a conductivity type of a corresponding one of the pair of DBRs adjacent to the one of the pair of cladding layers, at least one of the pair of cladding layers has a first impurity concentration, which is equal to or lower than a second impurity concentration of the corresponding one of the pair of DBRs and equal to or higher than a third impurity concentration of the other of the pair of DBRs.

In accordance with the surface emitting surface emission laser device, the boundary between the p-type region and the n-type region of the laser device can be located within the active layer structure. Since the bandgap of the active layer structure is lower than the bandgap of the cladding layer, the operating voltage of the laser device, which corresponds to the bandgap of the boundary between the p-type region and the n-type region, is lowered in the present invention compared to the operating voltage of the conventional laser device, wherein the boundary resides outside the active layer, e.g., within the cladding layer or at the boundary between the cladding layer and the DBR.

The above and other objects, features and advantages of the present invention will be more apparent from the following description, referring to the accompanying drawings.

### BRIEF DESCRIPTION OF THE DRAWINGS

FIG. 1 is a schematic sectional-perspective view illustrating the configuration of a conventional surface emitting semiconductor laser device.

FIG. 2 is a schematic sectional-perspective view illustrating the configuration of a surface emitting semiconductor laser device according to an embodiment.

FIG. 3 is a graph showing the characteristics of the surface emitting semiconductor laser devices according to the embodiment and the conventional one, wherein the operating voltage is plotted against the injection current for comparison.

### PREFERRED EMBODIMENTS OF THE INVENTION

Before describing preferred embodiments of the present invention, the principle of the present invention will be described for a better understanding of the present invention.

To address the above problems, the inventor focused attention on the fact that in a device, such as a surface emitting semiconductor laser device, having a p-n junction between a p-type region and an n-type region, the operating voltage of the device is generally determined by the bandgap energy of the boundary between the p-type region and the n-type region.

The AlGaAs crystal employed also as a material for the cladding layers is likely to be of p-type due to unintended doping under usual epitaxial conditions where the AlGaAs crystal layer is epitaxially grown without doping by the metal organic chemical vapor deposition. That is, in the conventional GaAs-based surface emitting semiconductor laser device, both the upper and lower cladding layers, which are to be undoped, are likely to be of p-type.

Accordingly, the boundary between the p-type region and the n-type region coincides with that between the n-type DBR and the cladding layer which are adjacent to each other. Consequently, the laser device has an operating voltage which is higher than or equal to the bandgap energy of the cladding layer.

In this context, the inventor considered that the operating voltage would have a value corresponding to the bandgap energy of the active layer if the boundary between the p-type region and the n-type region can be shifted into the active layer by doping the cladding layer adjacent to the n-type DBR with n-type impurities to be an n-type cladding layer.

Since the bandgap energy of the active layer is less than that of the cladding layer in the semiconductor laser device, an operating voltage less than that of the conventional surface emitting semiconductor laser device can be obtained by the above configuration.

The inventor also considered that there should be a specific amount of n-type dopant which can shift the above boundary between the p-type region and the n-type region into the active layer.

The inventor then found after a variety of studies that the above p-type DBR layers might be occasionally and unintentionally doped with n-type impurities, and it was effective to dope the cladding layer adjacent to the n-type DBR at a doping level greater than the doping level of the p-type DBR layers with n-type impurities and less than the doping level of the n-type DBR layers,

The inventor also found the following facts. The cladding layer which is likely to be of p-type even under an undoped condition can be doped to form an n-type cladding layer adjacent to the n-type DBR and thereby reducing the operating voltage. However, the cladding layer may become of n-type in an undoped condition depending on the property of a crystal growth system. For this reason, it is more effective that not only the cladding layer adjacent to the n-type DBR but also the cladding layer adjacent to the p-type DBR is doped with p-type impurities to form p-and n-type cladding layers, respectively,.

It is to be noted that at least a portion of the cladding layer adjacent to the active layer should be doped, in order to shift the boundary between the p-type region and the n-type region into the active layer.

In the forgoing description, the GaAs-based laser device having a QW structure made of GaAs-based semiconductors has been exemplified; however, the foregoing description is also applicable to another GaAs-based laser device having a QW structure made of GaInNAs-based semiconductors. The foregoing description is not limited to the GaAs-based laser devices, and also applicable to an InP-based laser device, for example, having a QW structure made of InGaAsP-based semiconductors, wherein an undoped InP cladding layer is likely to be of n-type.

The inventor completed the present invention after performing a variety of experiments based on the above ideas.

In a preferred embodiment of the present invention, each cladding layer is doped with the dopant having the same conductivity type as that for the dopant of the semiconductor multilayer reflector adjacent to the cladding layer so that the boundary between the p-type region and the n-type region is substantially located in the active layer.

In the present invention, the amount of doping depends on the impurity concentration of the semiconductor multilayer reflectors, and is such that the boundary between the p-type region and the n-type region is substantially located in the active layer.

It is not always necessary to dope the entire layers of the cladding layer. It is sufficient to dope at least a portion of each cladding layer adjacent to the active layer so far as the boundary between the p-type region and the n-type region of the DFB laser device is substantially located in the active layer.

In a specific embodiment of the present invention, the cladding layer has an impurity concentration of 1×10¹⁶cm⁻³ or more and 1×10¹⁸cm⁻³ or less.

For example, the impurity concentration of the cladding layers and the semiconductor multilayer reflectors may be measured by the secondary ion mass spectrometry (SIMS), for example.

The present invention allows the boundary between the p-type region and the n-type region to be substantially located in the active layer, thereby making it possible to reduce the operating voltage of the laser device down to the bandgap energy of the active layer.

The present invention is preferably applicable to AlGaAs-based or GaInNAs-based surface emitting semiconductor laser devices, for example, without being limited by the composition of the semiconductor substrate or compound semiconductor layers.

Now, the present invention will be described below in more detail and in accordance with a specific embodiment with reference to the accompanying drawings, wherein similar constituent elements are designated by the same reference numerals throughout the drawings. It is to be noted that in the following embodiment, the method of deposition, the composition and thickness of the compound semiconductor layers, the diameter of a mesa post, process conditions or the like are shown by way of example, and the present invention is not limited thereto.

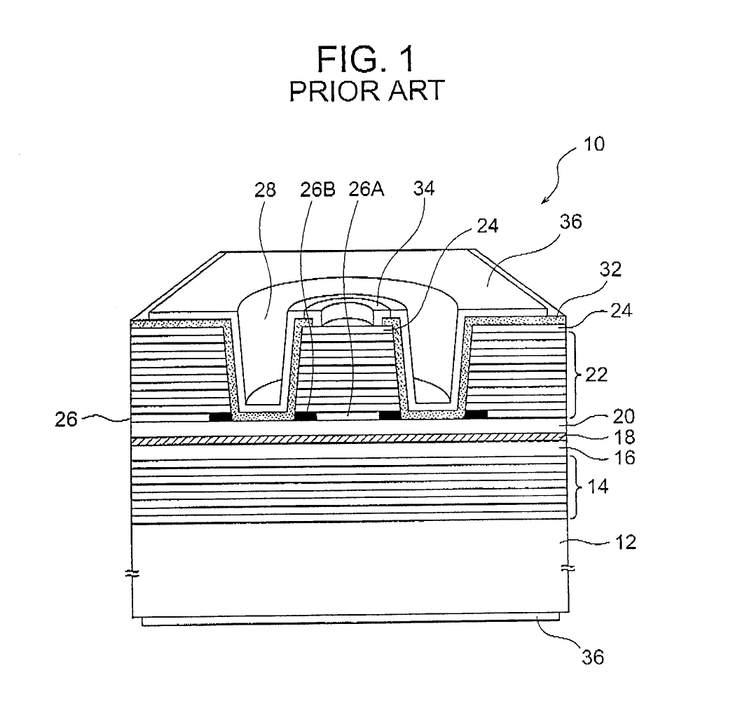

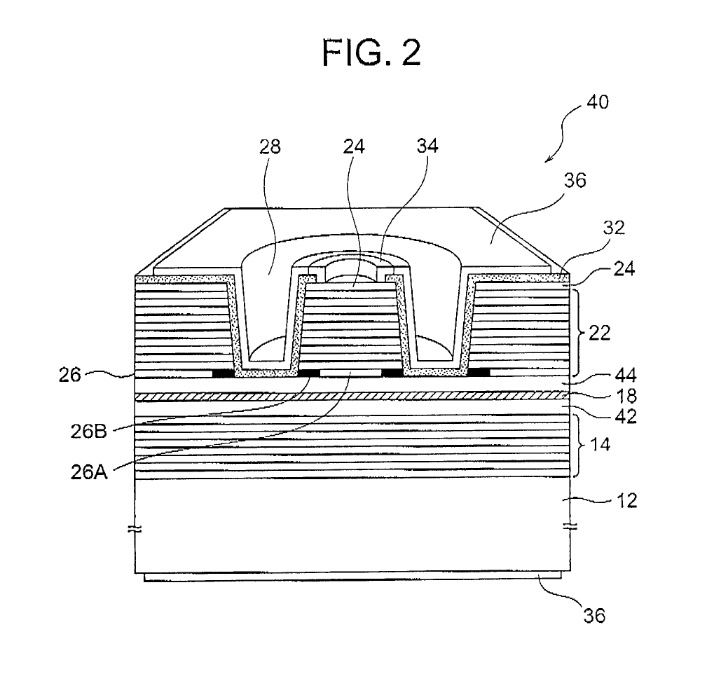

Referring to FIG. 2, a surface emitting semiconductor laser device 40 according to the present embodiment has a configuration similar to that of the conventional surface emitting semiconductor laser device 10 shown in FIG. 1, except that an Al_{0 3}Ga_{0.7}As lower cladding layer 42 is doped with n-type impurities to have an n-type impurity concentration of 3×10¹⁷cm⁻³ and an Al_{0.3}Ga_{0.7}As upper cladding layer 44 is doped with p-type impurities to have a p-type impurity concentration of 3×10¹⁷cm⁻³.

More specifically, the surface emitting semiconductor laser device 40 of the present embodiment has a layer structure formed on an n-GaAs substrate 12. The layer structure includes a lower semiconductor multilayer reflector (lower DBR) 14 including 35 n-Al_{0.2}Ga_{0 8}As/n-Al_{0 9}Ga_{0.1}As layer pairs, each layer having a thickness of λ/4 n (where λ is the lasing wavelength of the laser device and n is the refractive index of the each layer). The layer structure also includes an n-Al_{0.3}Ga_{0.7}As lower cladding layer 42 having an impurity concentration of 3×10¹⁷cm⁻³ and a thickness of 70 nm, a quantum well (QW) active layer structure 18, a p-Al_{0.3}Ga_{0 7}As upper cladding layer 20 having an impurity concentration of 3×10¹⁷cm⁻³ and a thickness of 70 nm, an upper semiconductor multilayer reflector (upper DBR) 22 including 20 p-Al_{0 2}Ga_{0.8}As/p-Al_{0.9}Ga_{0.1}As layer pairs, each layer having a thickness of λ/4 n (where λ is the lasing wavelength of the laser device and n is the refractive index of the each layer), and a p-GaAs cap layer 24 having a thickness of 10 nm.

In the layer structure as described above, the impurity concentration of the lower n-type DBR 14 is 3×10¹⁸cm⁻³ for the n-type dopant and 1×10¹⁷cm⁻³ for the p-type dopant. The impurity concentration of the upper p-type DBR 22 is 1×10¹⁸cm⁻³ for the p-type dopant and 1×10¹⁶cm⁻³ for the n-type dopant. It is to be noted that the p-type dopant of the lower n-type DBR 14 and the n-type dopant of the upper p-type DBR 22 are caused by unintentional doping.

One of the n-Al_{0.9}Ga_{0 1}As layers of the upper p-type DBR 22 closest to the QW active layer structure 18 is replaced by an AlAs layer 26. The AlAs layer 26 includes a current injection area 26A formed as a non-oxidized area of the AlAs layer 26 and a current confinement area 26B formed as an Al-oxidized area 30, wherein the Al content of the AlAs layer 26 is oxidized by selective oxidation thereof.

The QW active layer structure 18 has a GaAs/Al_{0.2}Ga_{0 8}As MQW structure that includes three GaAs QW layers having a thickness of 7 nm and associated Al_{0 2}Ga_{0 8}As barrier layers.

An annular groove 28 having a width of 20 μm is formed by a photolithographic and etching technique in the layer structure, so that the upper DBR 22 and the AlAs layer 26 are formed in the shape of a circular mesa post having a diameter of 45 μm at the central point thereof as viewed in the axial direction of the mesa post.

The Al content of the AlAs layer 26 is selectively oxidized from the periphery of the mesa post so as to form the current injection area 26A, or the non-oxidized area of the AlAs layer 26 in a central circular area having a diameter of 20 μm, and the current confinement area 26B, or the Al-oxidized area of the AlAs layer 26.

A SiNx film 32 is deposited as a protective film on the entire surface of the layer structure including the side-walls of the groove 28 except for the top surface of the mesa post. An annular electrode in contact with the p-GaAs cap layer 24 is also provided as a p-side electrode 34 made of an AuZn metal film on the top of the mesa post. In addition, a Ti/Pt/Au pad 36 is formed as an electrode lead in contact with the p-side electrode 34.

The rear side of the n-GaAs substrate 12 is polished to have a thickness of 100 μm, and thereafter an n-side electrode 38 made of an AuGeNi metal film is formed on the rear surface of the n-GaAs substrate 12.

A method for fabricating the surface emitting semiconductor laser device 40 of FIG. 2 will be described below.

First, the multilayer film including 35 n-Al_{0.2}Ga_{0 8}As/Al_{0 9}Ga_{0.1}As layer pairs are epitaxially grown on the n-GaAs substrate 12 by using a metal-organic chemical vapor deposition (MOCVD) to form the lower DBR 14.

Then, doping with n-type impurities is performed to form the Al_{0 3}Ga_{0.7}As lower cladding layer 42 having an impurity concentration of 1×10¹⁷cm⁻³ and a thickness of 70 nm on the lower DBR 14.

The deposition conditions are as follows:

Deposition materials: TMAl (trimethyl aluminum), TMGa (trimethyl gallium), and AsH₃ (arsine)

ratio (the ratio of V-group source gas to III-group source gas):

Doping gas: SiH₄ (silane) at a concentration of 1000 ppm and a flow rate of 2 cc/min

It is to be noted that H₂Se (selenium hydride) may be employed as an n-type dopant.

Then, the active layer structure 18 is formed on the lower cladding layer 42, where the QW active layer structure 18 has a GaAs/Al_{0 2}Ga_{0 8}As MQW structure including three GaAs QW layers each having a thickness of 7 nm and associated Al_{0.2}Ga_{0.8}As barrier layers. Then, using deposition conditions similar to the deposition conditions of the lower cladding layer 42 except for a different doping gas, the p-doped Al_{0.3}Ga_{0.7}As upper cladding layer 44 having a thickness of 70 nm is formed.

Doping gas: CBr₄ (carbon tetrabromide) having a concentration of 1000 ppm at a flow rate of 5 cc/min.

In the above conditions, CCl₄ (carbon tetrachloride) may be employed as a p-type dopant.

Then, the multilayer film including 20 p-Al_{0.2}Ga_{0 8}As/Al_{0.9}Ga_{0 1}As layer pairs is grown on the upper cladding layer 44 to form the upper DBR 22. One of the Al_{0.9}Ga_{0.1}As layer layers of the upper DBR 22 closest to the QW active layer structure 18 is replaced by the AlAs layer 26.

Then, the p-GaAs cap layer 24 having a thickness of 10 nm is grown on the upper DBR 22 to form a layer structure.

Then, a SiNx thin film (not shown) is deposited on the layer structure by using plasma-enhanced CVD, and a circular pattern having a diameter of about 45 μm is transferred onto the SiNx thin film using a photoresist film by photolithography.

Using this circular resist mask, the SiNx film is etched by reactive ion etching (RIE) with a CF₄ gas to form a circular pattern (not shown) of the SiNx film, followed by removing the resist.

Then, using the SiNx pattern as a mask and with a mixture of phosphoric acid, hydrogen peroxide, and water, the layer structure is etched in the shape of a groove down to the AlAs layer 26 to form the mesa post structure.

The layer structure in this state is then heated up to 400° C. in a steam ambient and maintained therein for about 25 minutes. During this period of time, the Al content of the AlAs layer 26 or the lowermost layer of the upper DBR 22 is selectively oxidized to form the Al-oxidized area 26B of the AlAs layer 26 that constitutes the current confinement area. The non-oxidized central area 26A having a diameter of about 20 μm withiin the AlAs layer 26 acts as a current injection path.

After the SiNx pattern has been completely removed by a RIE technique, another SiNx thin film 32 is deposited on the entire surface a by plasma-enhanced CVD technique. The SiNx thin film 32 on the mesa post is removed to leave a circle of diameter 25 μm, in which an annular AuZn metal film is formed as the p-side electrode 34. Then, the Ti/Pt/Au pad 36 is formed as an electrode lead so as to contact the p-side electrode 34.

After the n-GaAs substrate 12 has been polished to have a thickness of about 100 μm, an AuGeNi metal film is formed as the n-side electrode 38 by vapor deposition on the rear surface of the n-GaAs substrate 12.

Finally, the layer structure is annealed at about 400° C. in a nitrogen gas ambient, thereby completing the surface emitting semiconductor laser device 40.

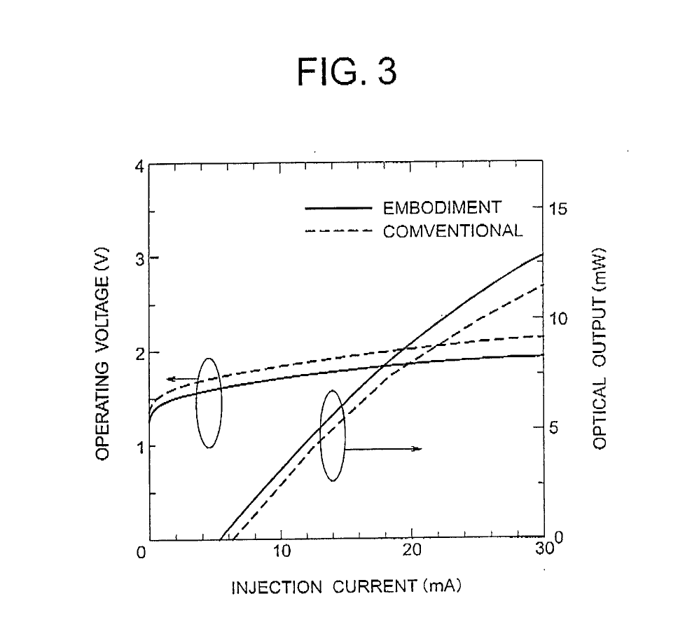

FIG. 3 shows the relationship between the injection current and the operating voltage and the relationship between the optical output power and the injection current, which were observed for the conventional surface emitting semiconductor laser device 10 and a sample of the surface emitting semiconductor laser device 40 of the present embodiment.

As can be seen from FIG. 3, the surface emitting semiconductor laser device 40 of the present embodiment has an excellent characteristic of the optical output power with respect to the injection current, a lower operating voltage than the conventional surface emitting semiconductor laser device 10. For example, the operating voltage is lower by 0.2V at an injection current of 20 mA.

In the present embodiment, the GaAs-based surface emitting semiconductor laser device has been exemplified. However, it is to be noted that the present invention is also applicable to surface emitting semiconductor laser devices other than the GaAs-based one, for example, to GaInNAs-based surface emitting semiconductor laser devices having a well layer made of a GaInNAs-based semiconductor. For example, for undoped InP cladding layers that are likely to become of n-type and used in an InP-based surface emitting semiconductor laser device, H₂Se (selenium hydroxide) may be employed as an n-type dopant and DEZn (diethyl zinc) as a p-type dopant. The cladding layers may be doped p-type and n-type with these dopants in the present invention. It is evident that the present invention does not depend on the conductivity type of the substrate.

According to the present invention, each cladding layer is doped with the dopant having the same conductivity type as that for the dopant of the semiconductor multilayer reflector close to the cladding layer so that the boundary between the p-type region and the n-type region is substantially located in the active layer. This makes it possible to reduce the operating voltage, which conventionally corresponds to the bandgap energy of the cladding layer, to a voltage that corresponds to the bandgap energy of the active layer which is lower than that of the cladding layer.

Since the above embodiments are described only for examples, the present invention is not limited to the above embodiments and various modifications or alterations can be easily made therefrom by those skilled in the art without departing from the scope of the present invention.

What is claimed is:

1. A surface emitting semiconductor laser device comprising a semiconductor substrate, pair of DBRs overlying said semiconductor substrate and having opposite conductivity types, a pair of cladding layers sandwiched between said pair of DBRs, each of said pair of cladding layers being adjacent to one of said DBRs, said pair of cladding layers having opposite conductivity types, an undoped active layer structure sandwiched between said pair of cladding layers, and a current confinement oxide layer disposed for confining injection current for said active layer structure,
each of said pair of cladding layers being doped with a dopant having a conductivity type same as a conductivity type of a corresponding one of said pair of DBRs adjacent to said one of said pair of cladding layers, at least one of said pair of cladding layers having a first impurity concentration, which is equal to or lower than a second impurity concentration of a corresponding one of said pair of DBRs and equal to or higher than a third impurity concentration of the other of said pair of DBRs.

2. The surface emitting semiconductor laser device according to claim 1, wherein one of said pair of cladding layers is doped with said dopant having a conductivity type same as a conductivity type of a dopant of a corresponding one of said pair of DBRs so that a boundary in said laser device between a first region having a first conductivity type and a second region having a second conductivity type resides within said active layer structure.

3. The surface emitting semiconductor laser device according to claim 1, wherein at least a portion of each of said cladding layers adjacent to said active layer structure is doped with said dopant.

4. The surface emitting semiconductor laser device according to claim 1, said first concentration resides between 1×10¹⁶ and 1×10¹⁸atoms/cm³.
